(19) United States
(12) Patent Application Publication
(10) Pub. No.: US 2025/0307132 A1
(43) Pub. Date: Oct. 2, 2025

(54) ROW AND COLUMN PAGE ACCESSES

(71) Applicant: Rambus Inc., San Jose, CA (US)

(72) Inventors: Thomas VOGELSANG, Jericho, VT (US); Brent Steven Haukness, Sunnyvale, CA (US)

(21) Appl. No.: 19/075,564

(22) Filed: Mar. 10, 2025

Related U.S. Application Data
(60) Provisional application No. 63/570,135, filed on Mar. 26, 2024.

(51) Int. Cl. G06F 12/02; G06F 12/0882

(52) U.S. Cl. CPC G06F 12/0207; G06F 12/0882

(57) ABSTRACT

A memory device has a row access page mode that concurrently activates the memory cells along one physical row of an array of memory array tiles (MATs) and also has a column access page mode that concurrently activates the memory cells along one physical row of each of a set of MATs that are not in the same row or column as the other MATs in the set. The memory device may store data representing the elements of a matrix of values. Each physical row of the memory array may store values that correspond to a row of the matrix. The row access page mode may be used to access a set of data corresponding to a row (or portion of a row) of the matrix. The column access page mode may be used to access a set of data corresponding to a column of the matrix.

### BRIEF DESCRIPTION OF THE DRAWINGS

FIGS. 1A-1C illustrate a memory system with row and column page accesses.

FIG. 2A-2D illustrate example memory system subarray activations for row page access and column page access.

FIGS. 3A-3D illustrate an example matrix row access and communication.

FIGS. 4A-4C illustrate an example matrix row access and communication.

FIGS. 5A-5C illustrate an example array architecture and operation.

FIG. 6 is a flowchart illustrating a method of operating a memory device.

FIG. 7 is a flowchart illustrating a method of operating a controller.

FIG. 8 is a flowchart illustrating a method of operating a memory controller to access a row page and a column page.

FIG. 9 is a flowchart illustrating a method of operating a memory device to access a row page and a column page.

FIG. 10 is a flowchart illustrating a method of operating a memory device.

FIG. 11 is a block diagram of a processing system.

### DETAILED DESCRIPTION OF THE EMBODIMENTS

In an embodiment, a memory device has a row access page mode (or command) that concurrently activates the memory cells along one physical row of an array of memory array tiles (MATs). The memory device also has a column access page mode (or command) that concurrently activates the memory cells along one physical row of each of a set of MATs that are not in the same row or column as the other MATs in the set. The memory device may store data representing the elements of a matrix of values. Each physical row of the memory array may store values that correspond to a row of the matrix, and groups of bits from sets of physical columns may store values that correspond to a column of the matrix. Thus, the row access page mode may be used to access a set of data corresponding to a row (or portion of a row) of the matrix. The column access page mode may be used to access a set of data corresponding to a column (or portion of a column) of the matrix. For the column page mode access, concurrently activating MATs that are not in either the same physical row or column of MATs allows access to the column data of the matrix using fewer activations than accessing the column data by iteratively activating a single row of MATs to access only a single column element (i.e., group of bits).

The descriptions and embodiments disclosed herein are made primarily with references to DRAM devices and DRAM memory arrays. This, however, should be understood to be a first example. It should be understood that other memory technologies may also benefit from the methods and/or apparatus described herein. These memory technologies include, but are not limited to static random access memory (SRAM), non-volatile memory (such as flash), conductive bridging random access memory (CBRAM—a.k.a., programmable metallization cell-PMC), resistive random access memory (a.k.a., RRAM or ReRAM), magnetoresistive random-access memory (MRAM), Spin-Torque Transfer (STT-MRAM), phase change memory (PCM), and the like, and/or combinations thereof. Accordingly, it should be understood that in the disclosures and/or descriptions given herein, these aforementioned technologies may be substituted for, included with, and/or encompassed within, the references to DRAM, DRAM devices, and/or DRAM arrays made herein.

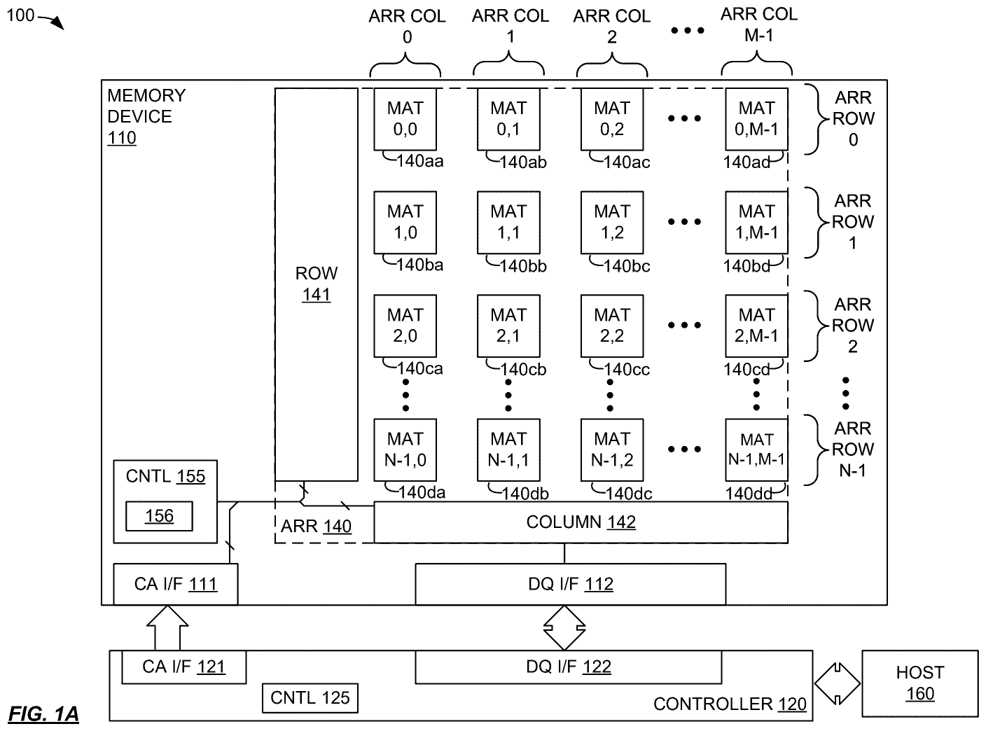

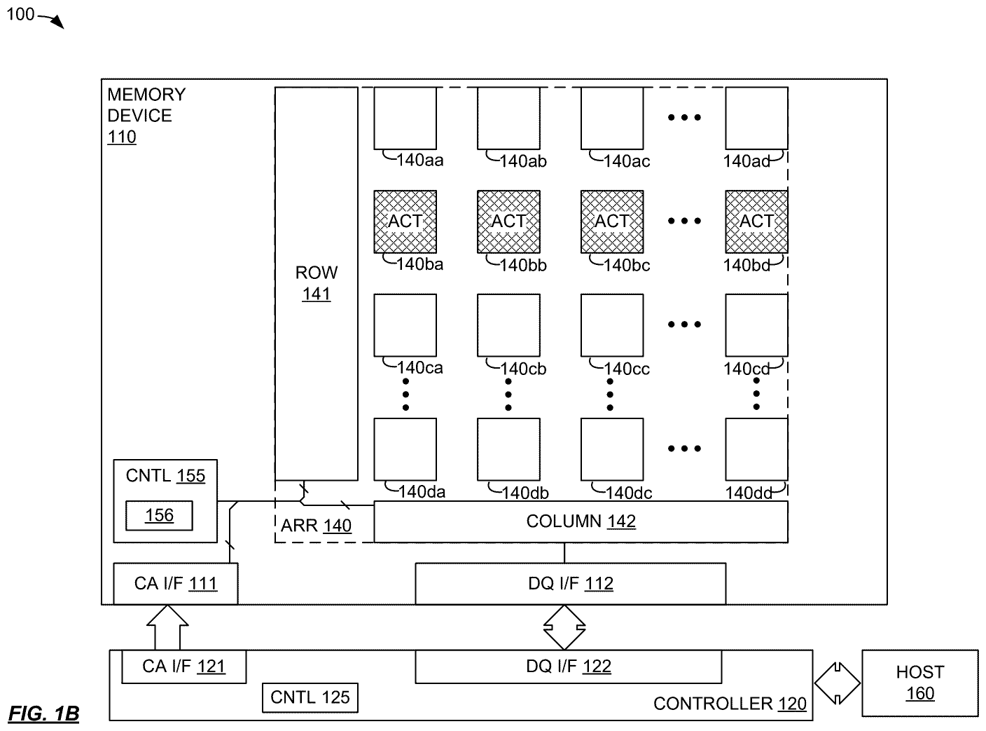

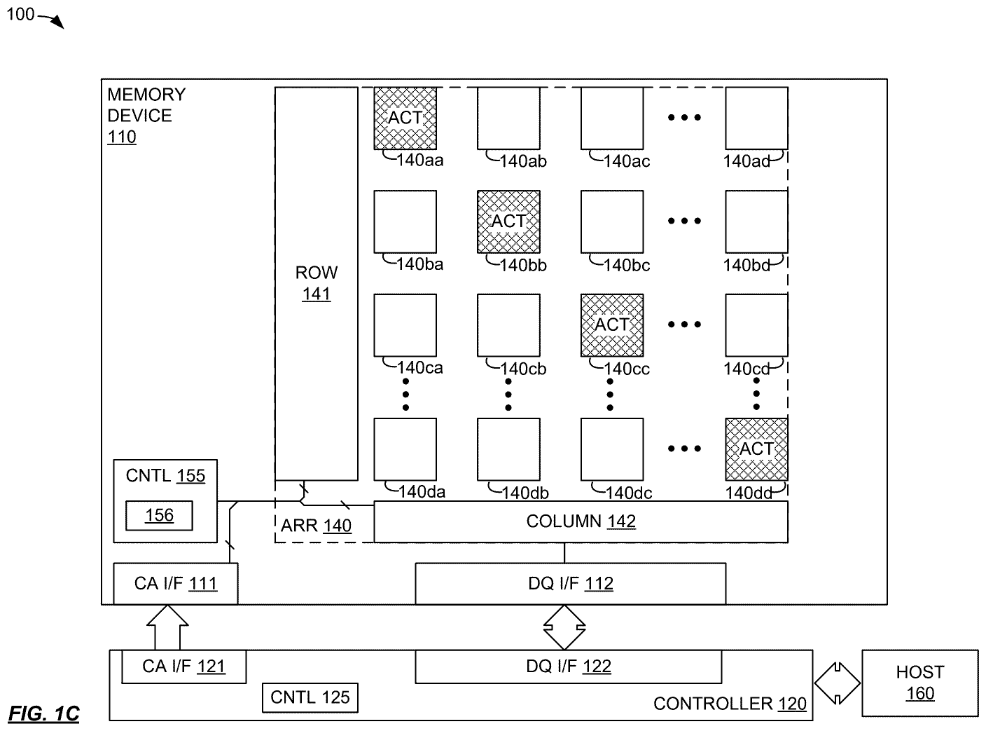

FIGS. 1A-1C illustrate a memory system with row and column page accesses. In FIGS. 1A-1C, memory system 100 comprises memory device 110, controller 120, and host 160. Memory device 110 includes command/address (CA) interface 111, data (DQ) interface 112, memory array (bank) 140, and control circuitry 155. Control circuitry 155 includes registers 156. The rows and columns of memory bank 140 may be arranged as rows (illustrated in FIG. 1A as array rows 0 to N−1) and columns (illustrated in FIG. 1A as array columns 0 to M−1) of memory array tiles (MATs) 140aa-140dd. Memory bank 140 also includes row circuitry 141 and column circuitry 142.

Memory controller 120 includes CA interface 121, DQ interface 122 and control circuitry 125. Controller 120 is operatively coupled to host 160. Host 160 and/or controller 120 may be operatively coupled to additional memory devices (not shown in FIG. 1).

CA interface 121 of controller 120 is operatively coupled to CA interface 111 of memory device 110. CA interface 121 of controller 120 is operatively coupled to CA interface 111 of memory device 110 to at least communicate, from controller 120 (e.g., under the control of control circuitry 125), commands and addresses to memory device 110. DQ interface 122 of controller 120 is operatively coupled to DQ interface 112 of memory device 110. DQ interface 122 of controller 120 is operatively coupled to DQ interface 112 of memory device 110 to communicate data (e.g., matrix element data) between controller 120 and memory device 110.

Memory controller 120 and memory device 110 may be integrated circuit type devices, such as are commonly referred to as “chips”. A memory controller, such as memory controller 120, manages the flow of data going to and from memory devices and/or memory modules. Memory device 110 may be a standalone device, or may be a component of a memory module such as a DIMM module used in servers. Memory device 110 may be, or be part of, a component having a “stack” of memory devices. Memory device 110 may be a device that adheres to, or is compatible with, a dynamic random access memory (DRAM) specification. A memory controller can be a separate, standalone chip, or integrated into another chip. For example, a memory controller 120 may be included on a single die with a microprocessor, included as a chip co-packaged with one or more microprocessor chips, included as part of a more complex integrated circuit system such as a block of a system on a chip (SOC), or be remotely coupled to one or more microprocessors via a fabric interconnect or other type of interconnect.

CA interface 111 of memory device 110 is operatively coupled to the row circuitry 141 of memory bank 140, the column circuitry 142 of memory bank 140, and control circuitry 155. CA interface 111 is operatively coupled to row circuitry 141 of memory banks 140 to at least activate rows in one or more of MATs 140aa-140dd. CA interface 111 is operatively coupled to the column circuitry 142 of memory bank 140 to at least sense values from activated rows, and to decode and provide the values of selected columns to other circuitry of memory device 110 (e.g., DQ interface 112, etc.) CA interface 111 is operatively coupled to the column circuitry 142 of each of memory banks 140 to at least allow accessing of data stored in MATs 140aa-140dd of memory bank 140 and to at least communicate data with DQ interface 112.

In an embodiment, memory device 110 may access data in a row page mode (e.g., under the control of control circuitry 155). A row page mode may be used to, for example, access a row (or partial row) of elements of a two-dimensional matrix of values. To access the row of elements, memory device 110 activates (e.g., based on a command from controller 120 and/or a mode indicator in registers 156) a row (e.g., using row circuitry 141) corresponding to a row address in a row of MATs. This is illustrated in FIG. 1B by MATs 140ba-140bd being filled with cross-hatching and each being labeled with the abbreviation “ACT”, while the remaining MATs (e.g., MAT 140ab) are unlabeled. Following activation, elements values of the row of the matrix may be accessed by iteratively accessing groups of bits, each corresponding to a matrix element (or partial matrix element—e.g., 8 bits of a 24 bit matrix element value) from column circuitry 142. The order the groups of bits are accessed may depend upon the order the elements of the row are stored in the activated row. The accessed elements (or partial elements) of the row of the matrix may be communicated with controller 120 and/or host 160.

Memory device 110 may also access data in a column page mode. A column page mode may be used to, for example, access a column (or partial column) of elements of the two-dimensional matrix of values. To access the column (e.g., based on a command from controller 120 and/or a mode indicator in registers 156) a single row (e.g., using row circuitry 141) corresponding to a row address in each of a set of MATs is activated. The set of MATs have one MAT from each column of MATs, where each of the MATs in the set is not in the same row of MATs as any other of the MATs in the set. This is illustrated in FIG. 1C by MAT 140aa, MAT 140bb, MAT 140cc, and MAT 140dd each being filled with cross-hatching, and each being labeled with the abbreviation “ACT”, while the remaining MATs (e.g., MAT 140ab) are unlabeled. Following activation, element values of the column of the matrix may be accessed by iteratively accessing groups of bits, each corresponding to a matrix element (or partial matrix element—e.g., 8 bits of a 24 bit matrix element value) from column circuitry 142. The order the groups of bits are accessed may depend upon the order the elements of the column are stored in each activated MAT 140bb, 140cc, 140dd. The accessed elements (or partial elements) of the column of the matrix may be communicated with controller 120 and/or host 160.

In an embodiment, whether memory device 110 accesses (and/or activates) memory bank 140, and communicates data in the manner of the row page mode may be based on a mode indicator (e.g., in registers 156 of control circuitry 155) and/or an indicator that is part of a command received by memory device 110 from controller 120. Similarly, whether memory device 110 accesses (and/or activates) memory bank 140, and communicates data in the manner of the column page mode may be based on a mode indicator (e.g., in registers 156 of control circuitry 155) and/or an indicator that is part of a command received by memory device 110 from controller 120.

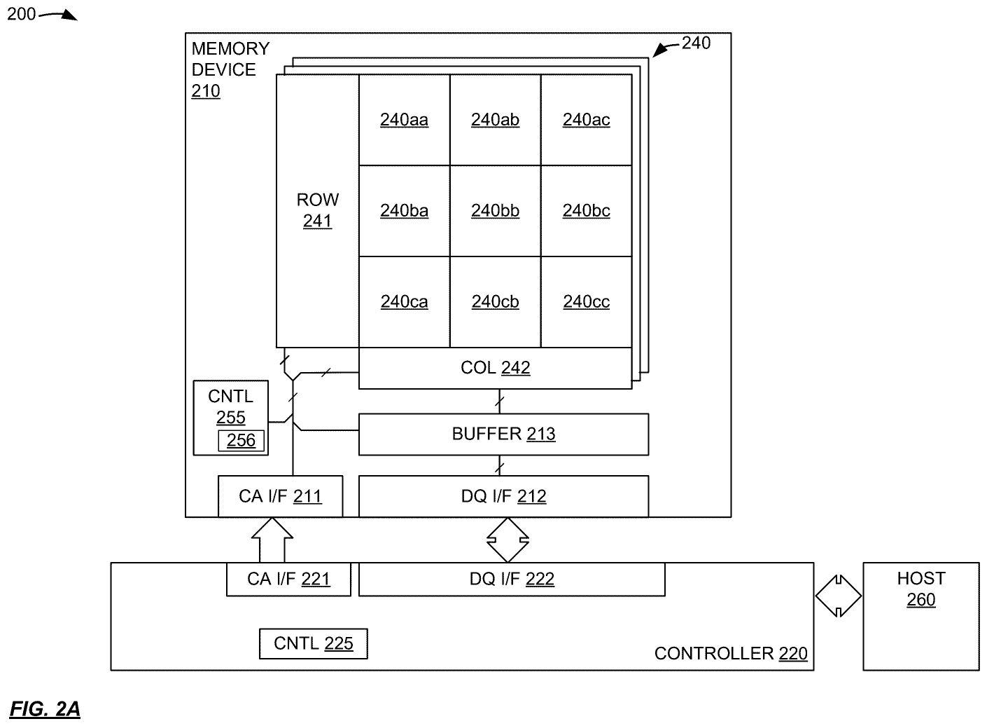

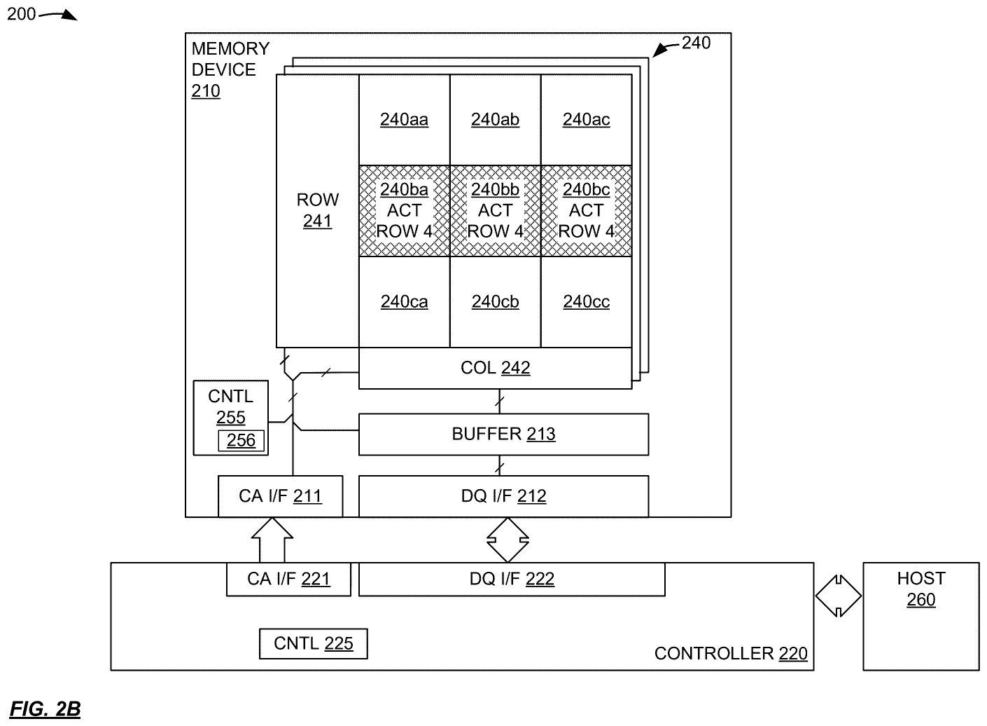

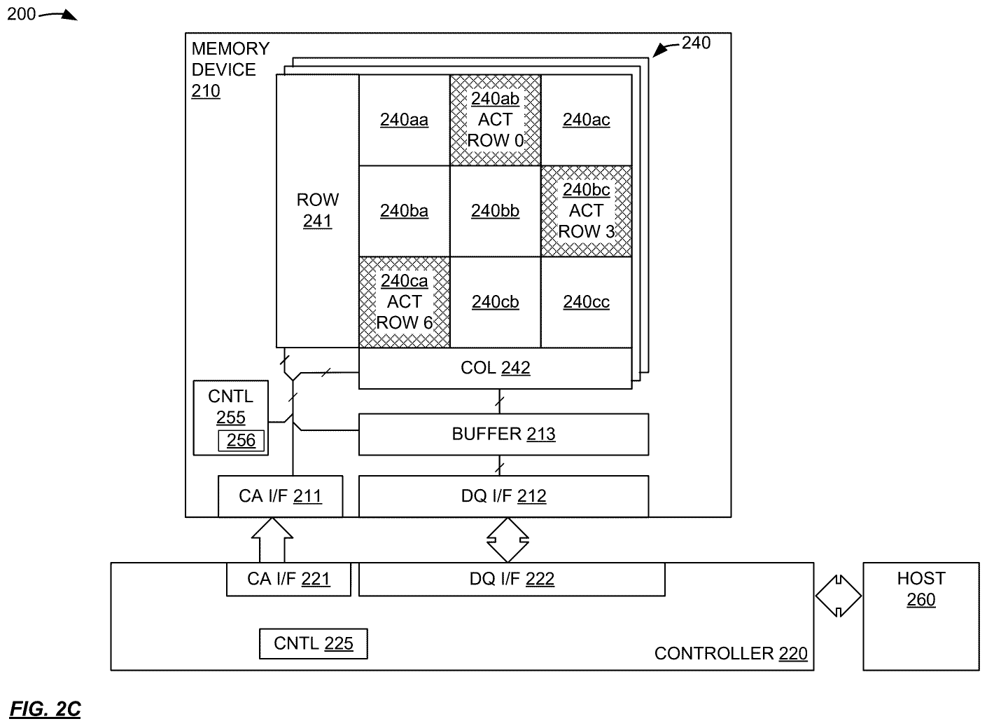

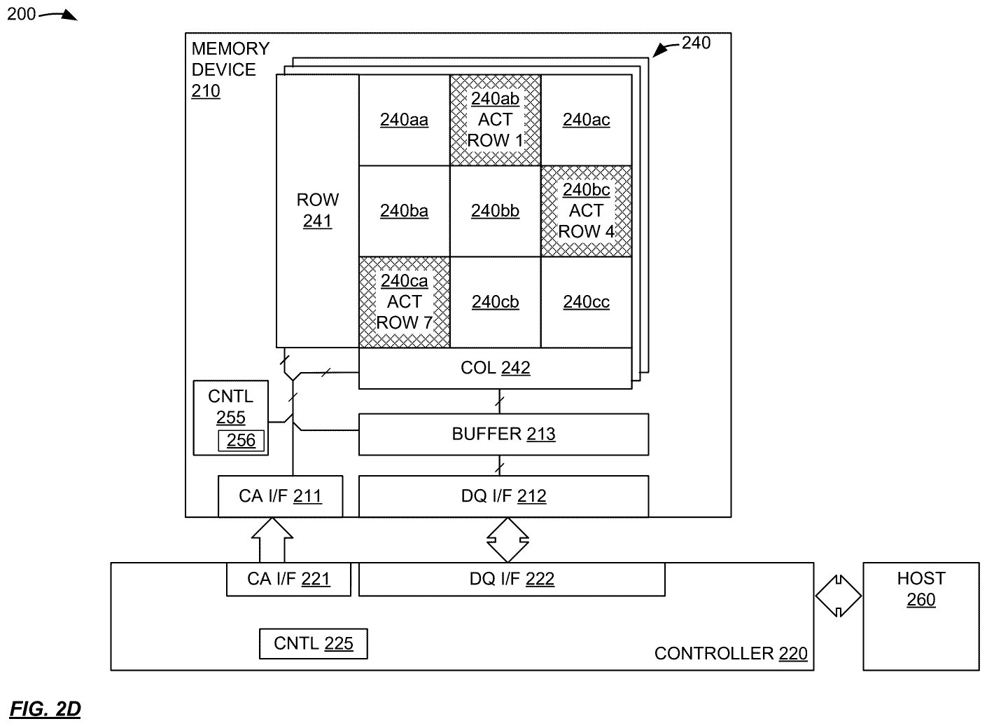

FIG. 2A-2E illustrate example memory system subarray activations for row page access and column page access. In FIGS. 2A-2E, memory system 200 comprises memory device 210, controller 220, and host 260. Memory device 210 includes command/address (CA) interface 211, data (DQ) interface 212, buffer 213, memory arrays (banks) 240, and control circuitry 255. Control circuitry 255 includes registers 256. The rows and columns of memory banks 240 may be arranged as rows and columns of MATs (e.g., MATs 240aa-240cc). Memory banks 240 also include row circuitry 241 and column circuitry 242.

Memory controller 220 includes CA interface 221, DQ interface 222, host interface 224, and control circuitry 225. Controller 220 is operatively coupled to host 260. Host 260 and/or controller 220 may be operatively coupled to additional memory devices (not shown in FIG. 2).

CA interface 221 of controller 220 is operatively coupled to CA interface 211 of memory device 210. CA interface 221 of controller 220 is operatively coupled to CA interface 211 of memory device 210 to at least communicate, from controller 220 (e.g., under the control of control circuitry 225), commands and addresses to memory device 210. DQ interface 222 of controller 220 is operatively coupled to DQ interface 212 of memory device 210. DQ interface 222 of controller 220 is operatively coupled to DQ interface 212 of memory device 210 to communicate data (e.g., matrix element data) between controller 220 and memory device 210.

Memory controller 220 and memory device 210 may be integrated circuit type devices, such as are commonly referred to as “chips”. A memory controller, such as memory controller 220, manages the flow of data going to and from memory devices and/or memory modules. Memory device 210 may be a standalone device, or may be a component of a memory module such as a DIMM module used in servers. Memory device 210 may be, or be part of, a component having a “stack” of memory devices. Memory device 210 may be a device that adheres to, or is compatible with, a dynamic random access memory (DRAM) specification. A memory controller can be a separate, standalone chip, or integrated into another chip. For example, a memory controller 220 may be included on a single die with a microprocessor, included as a chip co-packaged with one or more microprocessor chips, included as part of a more complex integrated circuit system such as a block of a system on a chip (SOC), or be remotely coupled to one or more microprocessors via a fabric interconnect or other type of interconnect.

CA interface 211 of memory device 210 is operatively coupled to the row circuitry 241 of memory bank 240, the column circuitry 242 of memory bank 240, and control circuitry 255. CA interface 211 is operatively coupled to row circuitry 241 of memory banks 240 to at least activate rows in one or more of MATs 240aa-240cc. CA interface 211 is operatively coupled to the column circuitry 242 of memory bank 240 to at least sense values from activated rows, and to decode and provide the values of selected columns to other circuitry of memory device 210 (e.g., buffer 213, DQ interface 212, etc.) CA interface 211 is operatively coupled to the column circuitry 242 of each of memory banks 240 to at least allow accessing of data stored in MATs 240aa-240cc of memory banks 240 and to at least communicate data with DQ interface 212 via buffer 213. Buffer 213 may be used to coalesce and/or reorder data from/to columns of memory bank 240 and DQ interface 212.

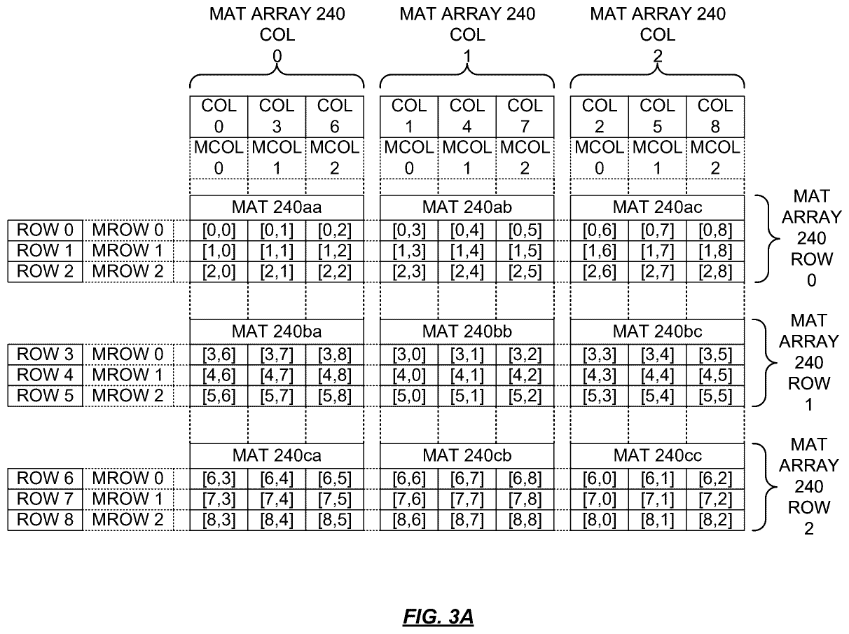

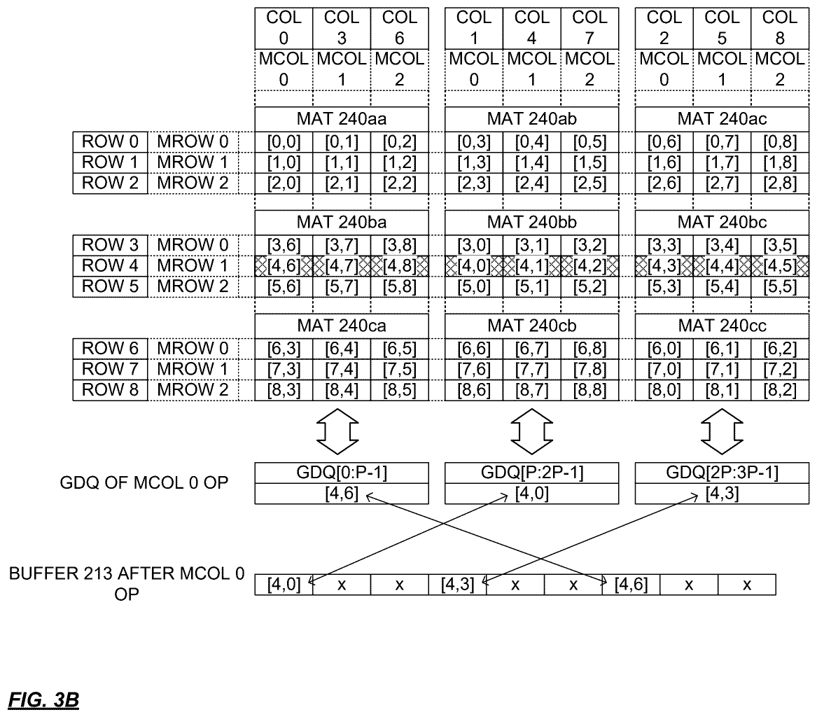

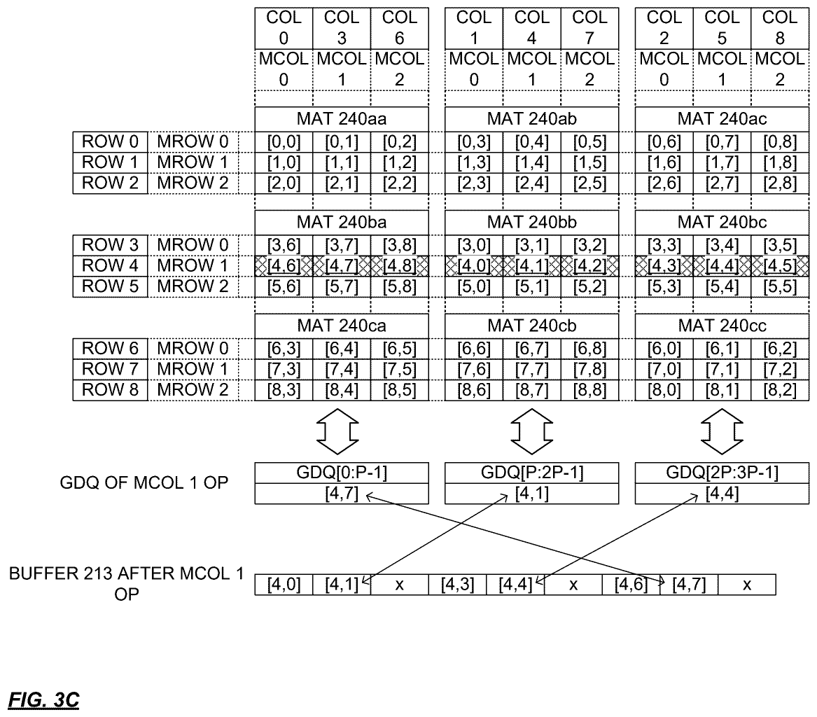

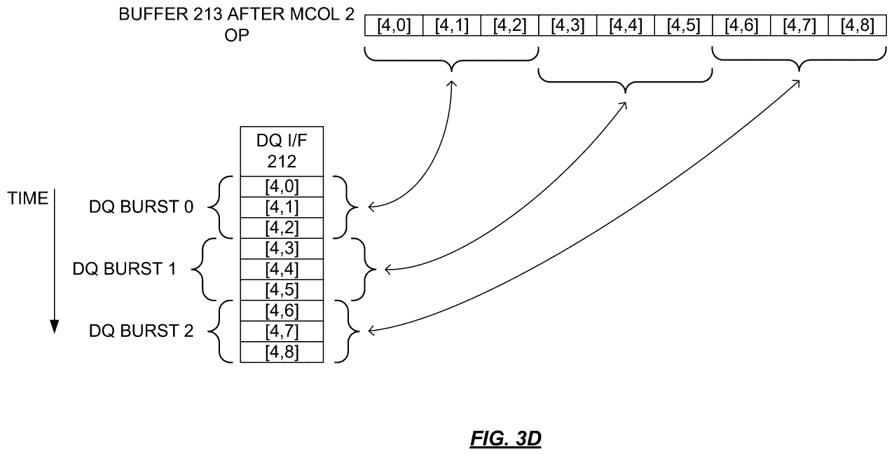

In an embodiment, memory device 210 may access data in a row page mode (e.g., under the control of control circuitry 255). A row page mode may be used to, for example, access a row (or partial row) of elements of a two-dimensional matrix of values. FIG. 3A illustrates an example storage pattern that maps elements of an 9×9 matrix (numbered herein from 0 to 9) to memory bank 240 rows, columns, and MATs. The example storage pattern illustrated in FIG. 3A is also disclosed in Table 1. For the purposes of clarity, matrix elements are denoted herein by their row and column position inside of brackets and separated by a comma. Thus, for example, the matrix element value in the 3^{rd} row and 6^{th} column of the matrix is denoted as [3,6].

TABLE 1

| | | Col addr | | | | | | | | |
|---|---|---|---|---|---|---|---|---|---|---|
| | | 0 | 3 | 6 | 1 | 4 | 7 | 2 | 5 | 8 |
| | | MAT Col | | | | | | | | |
| | | 0 | 1 | 2 | 0 | 1 | 2 | 0 | 1 | 2 |
| Row | MAT | | | | | | | | | |
| addr | Row | MAT 240aa | | | MAT 240ab | | | MAT 240ab | | |
| 0 | 0 | [0, 0] | [0, 1] | [0, 2] | [0, 3] | [0, 4] | [0, 5] | [0, 6] | [0, 7] | [0, 8] |
| 1 | 1 | [1, 0] | [1, 1] | [1, 2] | [1, 3] | [1, 4] | [1, 5] | [1, 6] | [1, 7] | [1, 8] |
| 2 | 2 | [2, 0] | [2, 1] | [2, 2] | [2, 3] | [2, 4] | [2, 5] | [2, 6] | [2, 7] | [2, 8] |
| | | MAT 240ba | | | MAT 240bb | | | MAT 240bc | | |
| 3 | 0 | [3, 6] | [3, 7] | [3, 8] | [3, 0] | [3, 1] | [3, 2] | [3, 3] | [3, 4] | [3, 5] |
| 4 | 1 | [4, 6] | [4, 7] | [4, 8] | [4, 0] | [4, 1] | [4, 2] | [4, 3] | [4, 4] | [4, 5] |
| 5 | 2 | [5, 6] | [5, 7] | [5, 8] | [5, 0] | [5, 1] | [5, 2] | [5, 3] | [5, 4] | [5, 5] |
| | | MAT 240ca | | | MAT 240cb | | | MAT 240cc | | |
| 6 | 0 | [6, 3] | [6, 4] | [6, 5] | [6, 6] | [6, 7] | [6, 8] | [6, 0] | [6, 1] | [6, 2] |
| 7 | 1 | [7, 3] | [7, 4] | [7, 5] | [7, 6] | [7, 7] | [7, 8] | [7, 0] | [7, 1] | [7, 2] |
| 8 | 2 | [8, 3] | [8, 4] | [8, 5] | [8, 6] | [8, 7] | [8, 8] | [8, 0] | [8, 1] | [8, 2] |

Note that the assignment of matrix columns to memory bank 240 MAT array columns is cyclically shifted at each MAT array row boundary. Thus, for example, MAT 240aa, which is in MAT array row 0, holds elements of array columns 0, 1, and 2. However, MAT 240ba, which is directly below MAT 240aa in MAT array row 1, holds elements of array columns 6, 7, and 8. The elements of array columns 0, 1, and 2 in MAT array row 1 are held by MAT 240bb—which is down one MAT array row, and over one MAT array column to the right from the position of the MAT holding columns 0, 1, and 2 in MAT row 0 (i.e., MAT 240aa).

To access the row of elements, memory device 210 activates (e.g., based on a command from controller 220 and/or a mode indicator in registers 256) a row (e.g., using row circuitry 241) corresponding to a row address (e.g., row address 4) in a row of MATs. This is illustrated in FIG. 2B by MATs 240ba-240bc being filled with cross-hatching and each being labeled with the abbreviation “ACT” and the indication that “ROW 4” is activated, while the remaining MATs (e.g., MAT 240ab) are unlabeled.

Following activation, the sense amplifiers of the activated MATs 240ba-240bc each contain an entire MAT row of data. However, in a typical DRAM architecture, only a fraction of the data of a MAT row can be communicated concurrently. The amount of data communicated concurrently to/from each MAT row is determined by the number of “global data” (a.k.a., global DQ and/or GDQ) signals provided by the DRAM architecture for communication with each MAT column. Thus, for example, if there are sixteen (16) global DQ signals provided for communication with each MAT column, then only 16-bits of data to/from each activated MAT 240aa-240bc can be communicated concurrently.

In FIGS. 3B-3D, each MAT column is illustrated as a GDQ width (e.g., P number of bits) sized word associated with one column of matrix elements. Thus, in FIGS. 3B-3D, the row of the matrix is accessed by iteratively using single column operations to access groups of bits from the activated MATs 240ba-240bc in GDQ width sized words, each corresponding to a matrix element (or partial matrix element—e.g., 16 bits of a 32 bit matrix element value) from column circuitry 242. However, as disclosed herein, other mappings from GDQ signals and number of column operations may be required to access each matrix element from an activated MAT 240ba-240bc.

FIGS. 3B-3D illustrate example operations to read a row matrix elements in row page mode from the MATs illustrated as activated in FIG. 2B. FIG. 3B illustrates a first column operation that communicates the value of matrix elements [4,6], [4,0], and [4, 3] respectively with activated MATs 240ba-240bc. In FIGS. 3B-3D, memory bank 240 row 4 (a.k.a., each of activated MATs 240ba-240bc MAT row 1-MROW 1) is illustrated as activated by being filled with cross-hatching. The column operations illustrated in FIG. 3B communicate, via global data signals GDQ[0:P−1] matrix column element [4,6] to/from MAT row 1 and MAT column 0 of MAT 240ba; communicate, via GDQ[P:2P−1] matrix column element [4,0], to/from MAT row 1 and MAT column 0 of MAT 240bb; and communicate, via GDQ[2P:3P−1] matrix column element [4,3], to/from MAT row 1 and MAT column 0 of MAT 240bc.

Note that the order of the columns of the matrix elements communicated concurrently via GDQ[0:3P−1] do not correspond to the word ordering in which they are communicated. Thus, for example, GDQ[0:P−1] lines, which start at the lowest numbered bit of the GDQ[ ] signals, communicate a matrix element from column 6 of the matrix—which is the highest numbered column of the elements that were communicated concurrently by the column operation illustrated in FIG. 3B. Thus, as illustrated in FIGS. 3B-3D, buffer 213 may be used by memory system 200 to reorder matrix elements from the column order illustrated in FIG. 3A to an order that corresponds to the column order of the matrix. This is illustrated in FIG. 3B by: the arrow running between matrix element [4,6] on GDQ[0:P−1] and the seventh (7^{th}) location or slot (counting left to right starting at 1) of buffer 213; the arrow running between matrix element [4,0] on GDQ[P:2P−1] and the first (1st) location (slot) of buffer 213; and the arrow running between matrix element [4,3] on GDQ[2P:3P−1] and the fourth (4^{th}) location (slot) of buffer 213. Thus, after the column operations illustrated in FIG. 3B, buffer 213 is illustrated with matrix element [4,0] in its first location, matrix element [4,3] in its fourth location, and matrix element [4,6] in its seventh location.

FIG. 3C illustrates a second column operation that communicates the value of matrix elements [4,7], [4,1], and [4, 4] respectively with activated MATs 240ba-240bc. The column operation illustrated in FIG. 3C may occur after the operations illustrated in FIG. 3B. The column operations illustrated in FIG. 3C communicate, via global data signals GDQ[0:P−1] matrix column element [4,7] to/from MAT row 1 and MAT column 1 of MAT 240ba; communicate, via GDQ[P:2P−1] matrix column element [4,1], to/from MAT row 1 and MAT column 1 of MAT 240bb; and communicate, via GDQ[2P:3P−1] matrix column element [4,4], to/from MAT row 1 and MAT column 1 of MAT 240bc.

As with FIG. 3B, the order of the columns of the matrix elements communicated concurrently via GDQ[0:3P−1] do not correspond to the word ordering in which they are communicated. Thus, as illustrated in FIGS. 3B-3D, buffer 213 may be used by memory system 200 to reorder matrix elements from the column order illustrated in FIG. 3A to an order that corresponds to the column order of the matrix. This is illustrated in FIG. 3C by: the arrow running between matrix element [4,7] on GDQ[0:P−1] and the seventh (8^{th}) location or slot (counting left to right starting at 1) of buffer 213; the arrow running between matrix element [4,1] on GDQ[P:2P−1] and the second (2^{nd}) location (slot) of buffer 213; and the arrow running between matrix element [4,4] on GDQ[2P:3P−1] and the fifth (5^{th}) location (slot) of buffer 213. Thus, after the column operations illustrated in FIG. 3C, buffer 213 is illustrated with matrix element [4,1] in its second location, matrix element [4,4] in its fifth location, and matrix element [4,7] in its eighth location.

Similar column operations may be performed to communicate matrix element [4,8] between MAT 240ba and the ninth location of buffer 213; communicate matrix element [4,2] between MAT 240bb and the third location of buffer 213; and communicate matrix element [4,5] between MAT 240bc and the sixth location of buffer 213. However, for the sake of brevity, these operations will not be illustrated herein by another Figure. Accordingly, from the foregoing, it should be understood that, in an embodiment, buffer 213 may be used to coalesce and reorder the data communicated with activated MATs 240ba-240bc via the GDQ[ ] signals.

FIG. 3D illustrates operations to communicate matrix elements between buffer 213 and controller 220 via DQ interface 212. In FIG. 3D, buffer 213 is illustrated with matrix elements from row 4 of the matrix in matrix column order (i.e., from left to right: [4,0], [4,1], [4,2], [4,3], [4,4], [4,5], [4,6], [4,7], [4,8]). FIG. 3D also illustrates three DQ bus bursts being communicated via DQ interface 212. DQ burst 0 is illustrated as communicating, in the following order and via DQ interface 212, matrix elements [4,0], [4,1], and [4,2]. DQ burst 1 is illustrated as communicating, in the following order and via DQ interface 212, matrix elements [4,3], [4,4], and [4,5]. DQ burst 2 is illustrated as communicating, in the following order and via DQ interface 212, matrix elements [4,6], [4,7], and [4,8].

Memory device 210 may also access data in a column page mode (e.g., under the control of control circuitry 255). A column page mode may be used to, for example, access a column (or partial column) of elements of the two-dimensional matrix of values. To access a first portion of the matrix elements of the matrix the column (e.g., based on a command from controller 220 and/or a mode indicator in registers 256) a first single row (e.g., using row circuitry 241) corresponding to a first MAT row address (but different memory bank 240 row addresses) in each of a set of MATs is activated. The set of MATs have one MAT from each column of MATs, where each of the MATs in the set is not in the same row of MATs as any other of the MATs in the set. This is illustrated in FIGS. 2C-2D by MAT 240ab, MAT 240bc, and MAT 240ca each being filled with cross-hatching, each being labeled with the abbreviation “ACT”, and being labeled with an array 240 row number that is activated, while the remaining MATs (e.g., MAT 240aa) are unlabeled. The memory bank 240 row addresses, 0, 3, and 6 in FIG. 2C, that are respectively activated in MAT 240ab, MAT 240bc, and MAT 240ca correspond to the same MAT row number (i.e., MAT row 0) in each of activated MAT 240ab, activated MAT 240bc, and activated MAT 240ca, but since each activated MAT is in a different physical row of MATs, have different memory bank 240 row addresses.

Following activation, a subset of the element values of the column of the matrix may be accessed by iteratively accessing groups of bits, each corresponding to a matrix element (or partial matrix element—e.g., 8 bits of a 24 bit matrix element value) from column circuitry 242. The order the groups of bits are accessed may depend upon the order the elements of the column are stored in each of MAT 240ab, MAT 240bc, and MAT 240ca. The accessed elements (or partial elements) of the column of the matrix may be communicated with controller 220 and/or host 260.

In an embodiment, whether memory device 210 accesses (and/or activates) memory bank 240, and communicates data in the manner of the row page mode may be based on a mode indicator (e.g., in registers 256 of control circuitry 255) and/or an indicator that is part of a command received by memory device 210 from controller 220. Similarly, whether memory device 210 accesses (and/or activates) memory bank 240, and communicates data in the manner of the column page mode may be based on a mode indicator (e.g., in registers 256 of control circuitry 255) and/or an indicator that is part of a command received by memory device 210 from controller 220.

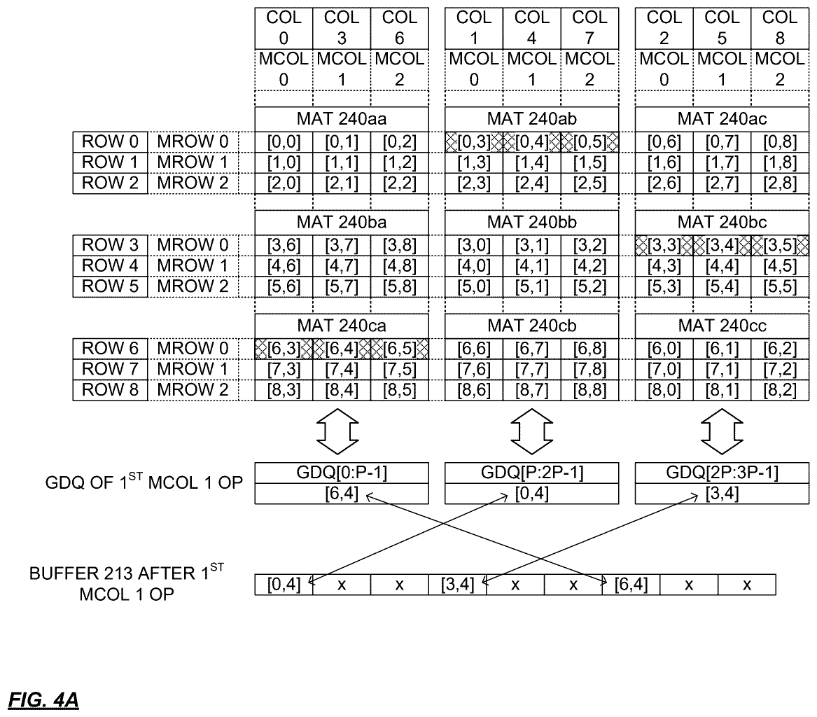

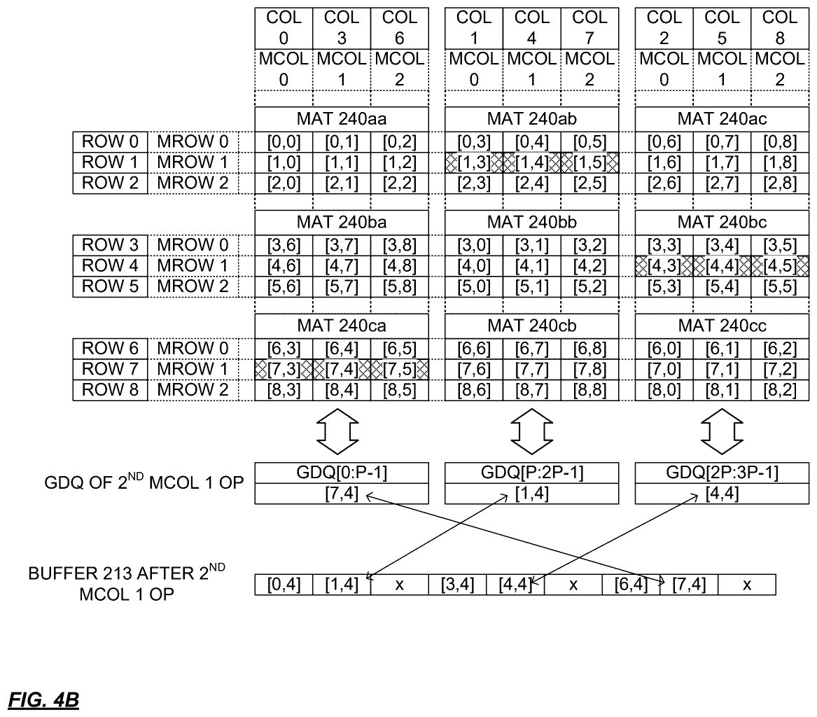

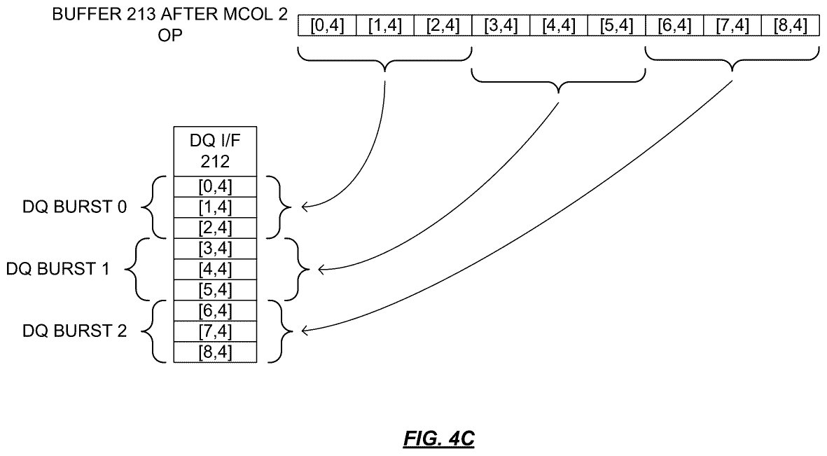

FIG. 4A illustrates a first example operations to read a first portion of a column of matrix elements in column page mode. FIG. 4A illustrates a first column operation that communicates the value of matrix elements [6,4], [0,4], and [3,4] respectively with MAT row 0 of activated MAT 240ab (memory bank 240 row 0), MAT row 0 of activated MAT 240bc (memory bank 240 row 3), and MAT row 0 of activated MAT 240ca (memory bank 240 row 6). In FIG. 4A, each MAT row 0 of each of activated MAT 240ab, activated MAT 240bc, and activated MAT 240ca is illustrated as activated by being filled with cross-hatching. The column operations illustrated in FIG. 4A communicate, via global data signals GDQ[0:P−1] matrix column element [6,4] to/from MAT row 0 and MAT column 1 of MAT 240ca (a.k.a., memory bank 240 row 6, column 3); communicate, via GDQ[P:2P−1] matrix column element [0,4], to/from MAT row 0 and MAT column 1 of MAT 240ab (a.k.a., memory bank 240 row 0, column 4); and communicate, via GDQ[2P:3P−1] matrix column element [3,4], to/from MAT row 0 and MAT column 1 of MAT 240bc (a.k.a., memory bank 240 row 3, column 5).

Note that the order of the rows of the matrix elements communicated concurrently via GDQ[0:3P−1] do not correspond to the word ordering they are communicated. Thus, for example, GDQ[0:P−1] lines, which start at the lowest numbered bit of the GDQ[ ] signals, communicate a matrix element from row 6 of the matrix—which is the highest numbered row of the elements that were communicated concurrently by the column operation illustrated in FIG. 4A. Thus, as illustrated in FIGS. 4A-4B, buffer 213 may be used by memory system 200 to reorder matrix elements from the row order illustrated in FIG. 3A to an order that corresponds to the row order of the matrix. This is illustrated in FIG. 4A by: the arrow running between matrix element [6,4] on GDQ[0:P−1] and the seventh (7^{th}) location or slot (counting left to right starting at 1) of buffer 213; the arrow running between matrix element [0,4] on GDQ[P:2P−1] and the first (1st) location (slot) of buffer 213; and the arrow running between matrix element [3,4] on GDQ[2P:3P−1] and the fourth (4^{th}) location (slot) of buffer 213. Thus, after the column operations illustrated in FIG. 4A, buffer 213 is illustrated with matrix element [0,4] in its first location, matrix element [3,4] in its fourth location, and matrix element [6,4] in its seventh location.

To access a second portion of the matrix elements of the matrix the column a second single row corresponding to a second MAT row address, different from the first MAT row address, in each of the set of MATs is activated. This is illustrated in FIG. 2D by MAT 240ab, MAT 240bc, and MAT 240ca each being filled with cross-hatching, each being labeled with the abbreviation “ACT”, and being labeled with a memory bank 240 MAT row number that is activated, while the remaining MATs (e.g., MAT 240aa) are unlabeled. The memory bank 240 row addresses, 1, 4, and 7 in FIG. 2D, that are respectively activated in MAT 240ab, MAT 240bc, and MAT 240ca correspond to the same MAT row number (i.e., MAT row 1) in each of activated MAT 240ab, activated MAT 240bc, and activated MAT 240ca, but since each activated MAT is in a different physical row of MATs, have different memory bank 240 row addresses from each other, and from the activated memory bank 240 row addresses illustrated in FIG. 4A.

Following activation, a subset of the element values of the column of the matrix may be accessed by iteratively accessing groups of bits, each corresponding to a matrix element (or partial matrix element—e.g., 8 bits of a 24 bit matrix element value) from column circuitry 242. The order the groups of bits are accessed may depend upon the order the elements of the column are stored in each activated MAT 240ab, MAT 240bc, and MAT 240ca. The accessed elements (or partial elements) of the column of the matrix may be communicated with controller 220 and/or host 260.

FIG. 4B illustrates a second example operations to read a second portion of the column of matrix elements in column page mode. FIG. 4B illustrates a second column operation that communicates the value of matrix elements [7,4], [1,4], and [4,4] respectively with MAT row 1 of activated MAT 240ca (memory bank 240 row 7), MAT row 1 of activated MAT 240bc (memory bank 240 row 1), and MAT row 1 of activated MAT 240ca (memory bank 240 row 4). In FIG. 4B, each MAT row 1 of each of activated MAT 240ab, activated MAT 240bc, and activated MAT 240ca is illustrated as activated by being filled with cross-hatching. The column operations illustrated in FIG. 4B communicate, via global data signals GDQ[0:P−1] matrix column element [7,4] to/from MAT row 1 and MAT column 1 of MAT 240ca (a.k.a., memory bank 240 row 7, column 3); communicate, via GDQ[P:2P−1] matrix column element [1,4], to/from MAT row 1 and MAT column 1 of MAT 240ab (a.k.a., memory bank 240 row 1, column 4); and communicate, via GDQ[2P:3P−1] matrix column element [4,4], to/from MAT row 1 and MAT column 1 of MAT 240bc (a.k.a., memory bank 240 row 4, column 5).

Note that the order of the rows of the matrix elements communicated concurrently via GDQ[0:3P−1] do not correspond to the word ordering they are communicated. Thus, for example, GDQ[0:P−1] lines, which start at the lowest numbered bit of the GDQ[ ] signals, communicate a matrix element from row 6 of the matrix—which is the highest numbered row of the elements that were communicated concurrently by the column operation illustrated in FIG. 4A. Thus, as illustrated in FIGS. 4A-4B, buffer 213 may be used by memory system 200 to reorder matrix elements from the row order illustrated in FIG. 3A to an order that corresponds to the row order of the matrix. This is illustrated in FIG. 4B by: the arrow running between matrix element [7,4] on GDQ[0:P−1] and the eighth (8^{th}) location or slot (counting left to right starting at 1) of buffer 213; the arrow running between matrix element [1,4] on GDQ[P:2P−1] and the second (2nd) location (slot) of buffer 213; and the arrow running between matrix element [4,4] on GDQ[2P:3P−1] and the fifth (5^{th}) location (slot) of buffer 213. Thus, after the column operations illustrated in FIG. 4B, buffer 213 is illustrated with matrix element [1,4] in its second location, matrix element [4,4] in its fifth location, and matrix element [7,4] in its eighth location.

Similar column operations may be performed to communicate matrix element [8,4] between MAT 240ca and the ninth location of buffer 213; communicate matrix element [2,4] between MAT 240ab and the third location of buffer 213; and communicate matrix element [5,4] between MAT 240bc and the sixth location of buffer 213. However, for the sake of brevity, these operations will not be illustrated herein by another Figure. Accordingly, from the foregoing, it should be understood that, in an embodiment, buffer 213 may be used to coalesce and reorder the data communicated with activated MATs 240ba-240bc via the GDQ[ ] signals.

FIG. 4C illustrates operations to communicate matrix elements between buffer 213 and controller 220 via DQ interface 212 in column page mode. In FIG. 4C, buffer 213 is illustrated with matrix elements from column 4 of the matrix in matrix row order (i.e., from left to right: [0,4], [1,4], [2,4], [3,4], [4,4], [5,4], [6,4], [7,4], [8,4]). FIG. 4C also illustrates three DQ bus bursts being communicated via DQ interface 212. DQ burst 0 is illustrated as communicating, in the following order and via DQ interface 212, matrix elements [0,4], [1,4], and [2,4]. DQ burst 1 is illustrated as communicating, in the following order and via DQ interface 212, matrix elements [3,4], [4,4], and [5,4]. DQ burst 2 is illustrated as communicating, in the following order and via DQ interface 212, matrix elements [6,4], [7,4], and [8,4].

In an embodiment, memory bank 140 and/or memory bank 240 may have N rows of MATs (numbered herein from 0 to N−1), M columns of MATs (numbered herein from 0 to M−1), where each MAT has R rows (wordlines) of memory cells (numbered herein from 0 to R−1), and C columns (bitlines) of memory cells (numbered herein from 0 to C−1), and each MAT is accessed using B number of global (GDQ) signals, where N, M, R, C and B are positive integers (e.g., 16, 256, 512, 1024, etc.). Thus, one set of B bits per MAT is accessed via the GDQ signals during each column access operation resulting in M×B bits being accessed via the GDQ signals of the array. In the following equations, the variable n indexes the matrix element row and the variable m indexes the matrix element column. Thus, for example, n=4 and m=3 indexes to matrix element [4, 3]. Similarly, the variable i indexes the array row address and the variable j indexes the array column address. The MAT row that is accessed is denoted as si, where the subscript l corresponds the numbering of the column of the MAT (e.g., MAT column 0 of the array is denoted with l=0, MAT column 1 with l=1, MAT column 2 with l=2, etc.). Thus, for example, s₄=5 means MAT array column number 4 is accessed via local-global data switches in MAT array row number 5. Similarly, mₜ denotes the matrix column number accessed via the GDQs of MAT array column 1 and nₜ denotes the matrix column number accessed via the GDQs of MAT array column 1. To determine the matrix elements and or MATS and GDQs for an example matrix to MAT and GDQ mapping accessed over a row page mode access, j is stepped from 0 to C−1 and the following equations are applied:

$${s}_{l} = ⌊ \frac{n}{R} ⌋$$

$$i = n$$

$${m}_{l} = j + C \times mod ( l + M - {s}_{l} , M ) .$$

To determine the matrix elements and or MATS and GDQs for the example matrix to MAT and GDQ mapping accessed over a column page mode access, i is stepped from 0 to R−1 and the following equations are applied:

$${s}_{l} = mod ( l + M - ⌊ \frac{m}{C} ⌋ , M )$$

$${n}_{l} = i + R \times {s}_{l}$$

$$j = mod ( m , C ) .$$

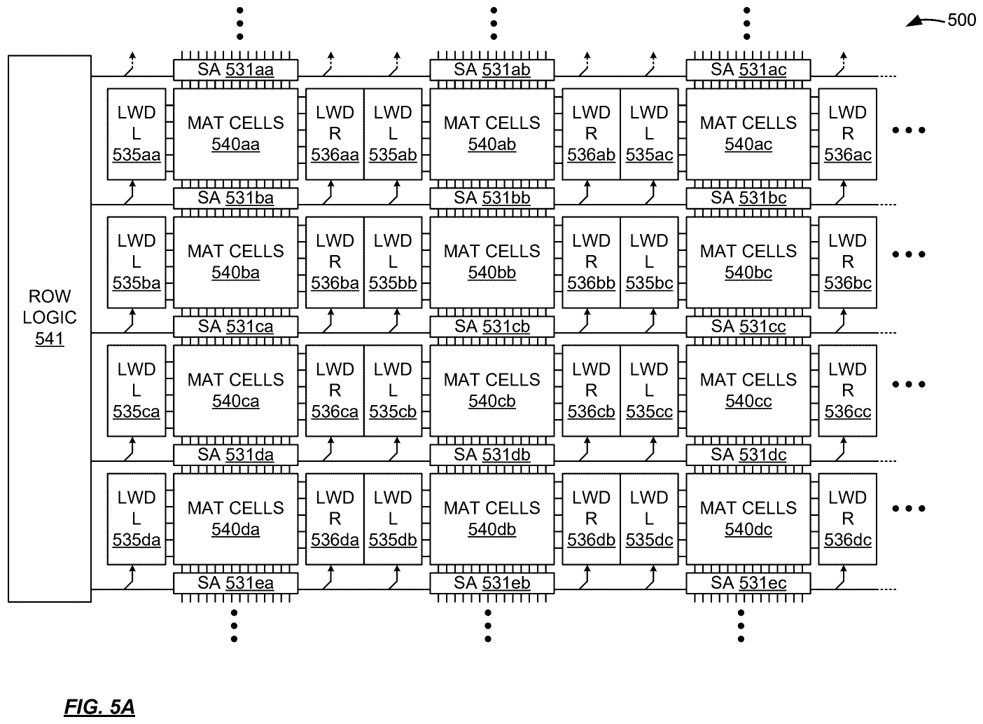

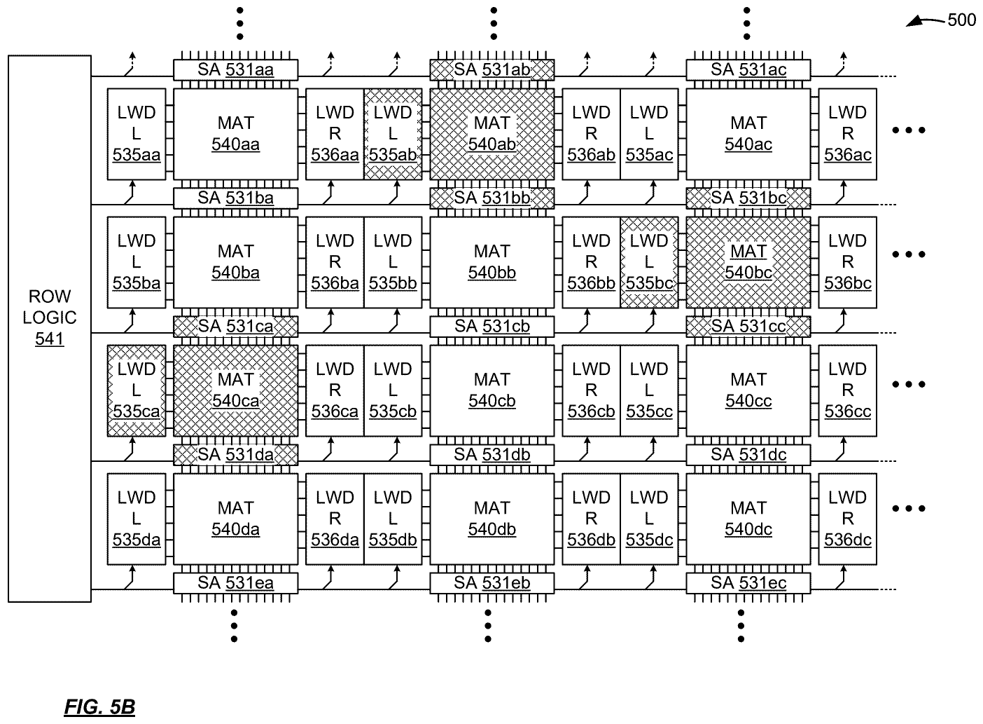

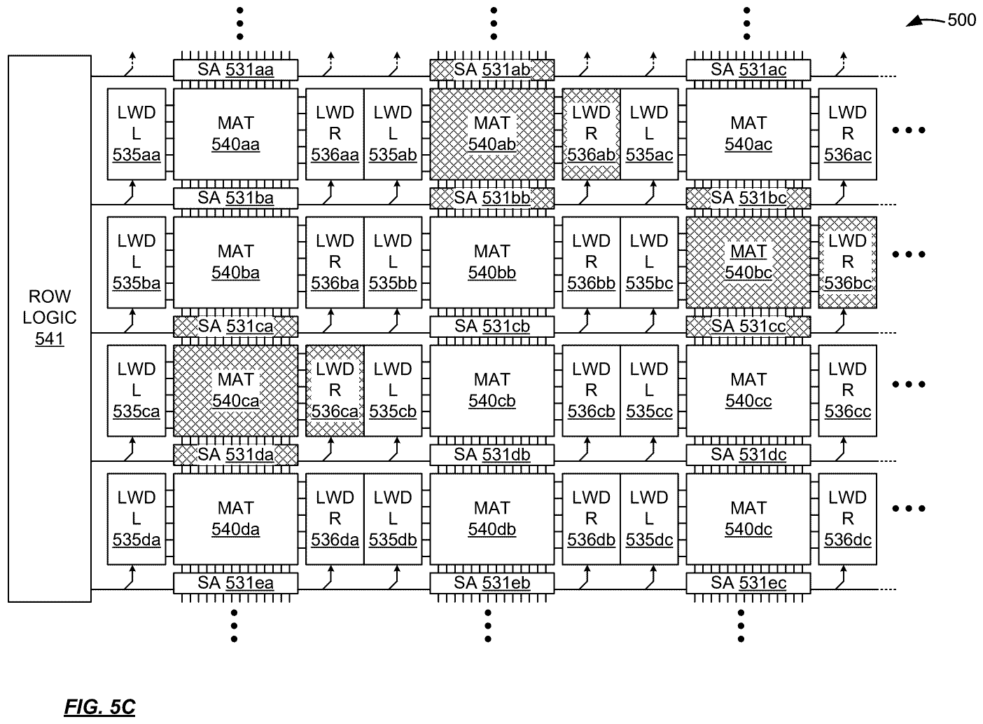

FIGS. 5A-5C illustrate an example array architecture and operation. The architecture illustrated in FIGS. 5A-5C may be used by memory device 110 and/or memory device 210. In FIGS. 5A-5C, memory array 500 comprises MAT memory cell arrays 540aa-540dc arranged into rows and columns. Between each MAT memory cell array 540aa-540dc and immediately adjacent in the vertical direction are shared sense amplifiers 531aa-531ec.

Between row logic 541 and a first column of MAT memory cell arrays 540aa-540da are left side of MAT local wordline drivers 535aa-535da that are respectively operatively coupled to MAT memory cell arrays 540aa-540da. To the right of the first column of MAT memory cell arrays 540aa-540da are right side of MAT local wordline drivers 536aa-536da that are respectively operatively coupled to MAT memory cell arrays 540aa-540da. Similarly, between right side of MAT local wordline drivers 536aa-536da and a second column of MAT memory cell arrays 540ab-540db are left side of MAT local wordline drivers 535ab-535db that are respectively operatively coupled to MAT memory cell arrays 540ab-540db. To the right of the second column of MAT memory cell arrays 540ab-540db are right side of MAT local wordline drivers 536ab-536db that are respectively operatively coupled to MAT memory cell arrays 540ab-540db. Finally, in FIGS. 5A-5C, between right side of MAT local wordline drivers 536ab-536db and a third column of MAT memory cell arrays 540ac-540dc are left side of MAT local wordline drivers 535ac-535dc that are respectively operatively coupled to MAT memory cell arrays 540ac-540dc. To the right of the third column of MAT memory cell arrays 540ac-540dc are right side of MAT local wordline drivers 536ac-536dc that are respectively operatively coupled to MAT memory cell arrays 540ac-540dc.

In an embodiment, left side of MAT local wordline drivers 535aa-535dc and right side of MAT local wordline drivers 536aa-536dc do not drive local wordlines in more than one MAT memory cell array 540ac-540dc. Thus, rows of memory cells in each of MAT memory cell arrays 540ac-540dc may be accessed independent of the other of MAT the memory cell arrays 540ac-540dc.

Row logic 541 is operatively coupled to left side of MAT local wordline drivers 535aa-535dc, sense amplifiers 531aa-531ec, and right side of MAT local wordline drivers 536aa-536dc. Row logic 541 is operatively coupled to left side of MAT local wordline drivers 535aa-535dc and right side of MAT local wordline drivers 536aa-536dc to enable independent access of MAT memory cell arrays 540aa-540dc without the need to access any MATs on an intervening row between two accessed rows due to shared circuitry between a MAT in the intervening row and a MAT in at least one of the accessed rows. In an embodiment, in addition to wordline selection signals provided by row logic 541, MAT selection signals are provided by row logic 541 to left side of MAT local wordline drivers 535aa-535dc, sense amplifiers 531aa-531ec, and right side of MAT local wordline drivers 536aa-536dc to enable the independent access described.

FIG. 5B illustrates an independent access/activation of a first set of MATs using left side of MATs local wordline drivers. In FIG. 5B, MAT memory cell array 540ca is activated using left side of MAT local wordline drivers 535ca (e.g., for an even numbered MAT row address), and the values read from MAT memory cell array 540ca are sensed and stored by sense amplifiers 531ca and sense amplifiers 531da. This is illustrated in FIG. 5B by the cross hatching in MAT memory cell array 540ca, left side of MAT local wordline drivers 535ca, sense amplifiers 531ca, and sense amplifiers 531da. MAT memory cell array 540ab is activated using left side of MAT local wordline drivers 535ab, and the values read from MAT memory cell array 540ab are sensed and stored by sense amplifiers 531ab and sense amplifiers 531b. This is illustrated in FIG. 5B by the cross hatching in MAT memory cell array 540ab, left side of MAT local wordline drivers 535ab, sense amplifiers 531ab, and sense amplifiers 531bb. MAT memory cell array 540bc is activated using left side of MAT local wordline drivers 535bc, and the values read from MAT memory cell array 540bc are sensed and stored by sense amplifiers 531bc and sense amplifiers 531cc. This is illustrated in FIG. 5B by the cross hatching in MAT memory cell array 540bc, left side of MAT local wordline drivers 535bc, sense amplifiers 531bc, and sense amplifiers 531bc.

FIG. 5C illustrates an independent access/activation of a second set of MATs using right side of MATs local wordline drivers. In FIG. 5C, MAT memory cell array 540ca is activated using right side of MAT local wordline drivers 536ca (e.g., for an odd numbered MAT row address), and the values read from MAT memory cell array 540ca are sensed and stored by sense amplifiers 531ca and sense amplifiers 531da. This is illustrated in FIG. 5B by the cross hatching in MAT memory cell array 540ca, right side of MAT local wordline drivers 536ca, sense amplifiers 531ca, and sense amplifiers 531da. MAT memory cell array 540ab is activated using right side of MAT local wordline drivers 536ab, and the values read from MAT memory cell array 540ab are sensed and stored by sense amplifiers 531ab and sense amplifiers 531b. This is illustrated in FIG. 5B by the cross hatching in MAT memory cell array 540ab, right side of MAT local wordline drivers 536ab, sense amplifiers 531ab, and sense amplifiers 531bb. MAT memory cell array 540bc is activated using right side of MAT local wordline drivers 536bc, and the values read from MAT memory cell array 540bc are sensed and stored by sense amplifiers 531bc and sense amplifiers 531cc. This is illustrated in FIG. 5C by the cross hatching in MAT memory cell array 540bc, right side of MAT local wordline drivers 536bc, sense amplifiers 531bc, and sense amplifiers 531bc.

It should be understood from the foregoing that the architecture illustrated and described herein with reference to FIG. 5A-5C whereby each of MAT memory cell arrays 540aa-540dc do not share either left side of MAT local wordline drivers 535aa-535dc or right side of MAT local wordline drivers 536aa-536dc with any other of MAT memory cell arrays 540aa-540dc, and independent operation thereof, allows independent access of MAT memory cell arrays 540aa-540dc without the need to refrain from accessing any MATs on intervening rows that are physically between rows having MATs that are being accessed.

FIGS. 5A-5C illustrate three columns of MAT memory cell arrays 540aa-540dc, associated sense amplifiers 531aa-531ec, left side of MAT local wordline drivers 535aa-535dc, and right side of MAT local wordline drivers 536aa-536dc. However, this is done merely for the purposes of illustration and brevity. It should be understood that additional rows and/or columns following the same general arrangement, structure, and interconnection are contemplated.

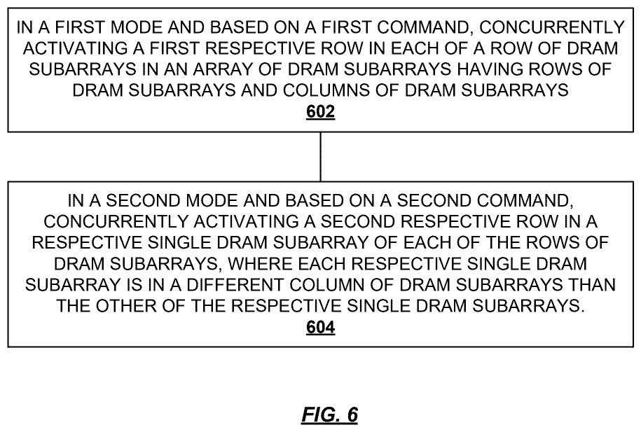

FIG. 6 is a flowchart illustrating a method of operating a memory device. One or more steps illustrated in FIG. 6 may be performed by, for example, memory system 100, memory system 200, memory array 500, and/or their components. In a first mode and based on a first command, a first respective row in each of a row of DRAM subarrays in an array of DRAM subarrays having rows of DRAM subarrays and columns of DRAM subarrays are activated (602). For example, based on a first command received from controller 120, memory device 110 may activate a first selected row in each of MATs 140ba-140bd which are all in the same row of MATs (i.e., memory bank 140's row 1).

In a second mode and based on a second command, a second row in a respective single DRAM subarray of each of the rows of DRAM subarrays is activated, where each respective single DRAM subarray is in a different column of DRAM subarrays than the other of the respective single DRAM subarrays (604). For example, based on a second command received from controller 120, memory device 110 may activate a second selected row in each of MATs 140aa, 140bb, 140cc, and 140dd which are all in different MAT columns and different MAT rows of the array of memory bank 140.

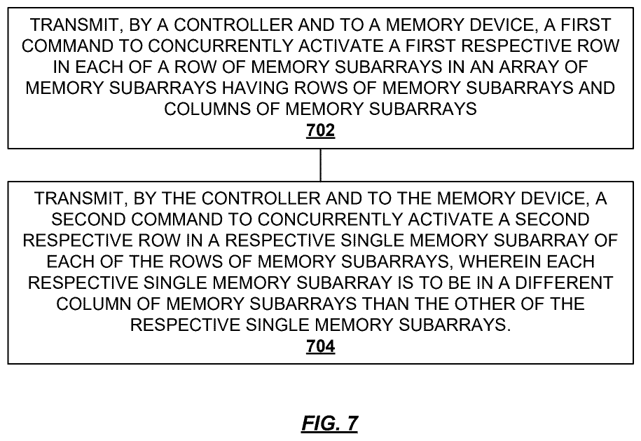

FIG. 7 is a flowchart illustrating a method of operating a controller. One or more steps illustrated in FIG. 7 may be performed by, for example, memory system 100, memory system 200, memory array 500, and/or their components. By a controller and to a memory device, a first command is transmitted to concurrently activate a first respective row in each of a row of DRAM subarrays in an array of DRAM subarrays having rows of DRAM subarrays and columns of DRAM subarrays (702). For example, controller 120 may transmit, to memory device 110, a first command to activate a first selected row in each of MATs 140ba-140bd which are all in the same row of MATs (i.e., memory bank 140's MAT row 1).

By the controller and to the memory device, a second command is transmitted to concurrently activate a second row in a respective single DRAM subarray of each of the rows of DRAM subarrays, where each respective single DRAM subarray is in a different column of DRAM subarrays than the other of the respective single DRAM subarrays (704). For example, controller 120 may transmit, to memory device 110, a second command to activate a second selected row in each of MATs 140aa, 140bb, 140cc, and 140dd which are all in different MAT columns and different MAT rows of the array of memory bank 140.

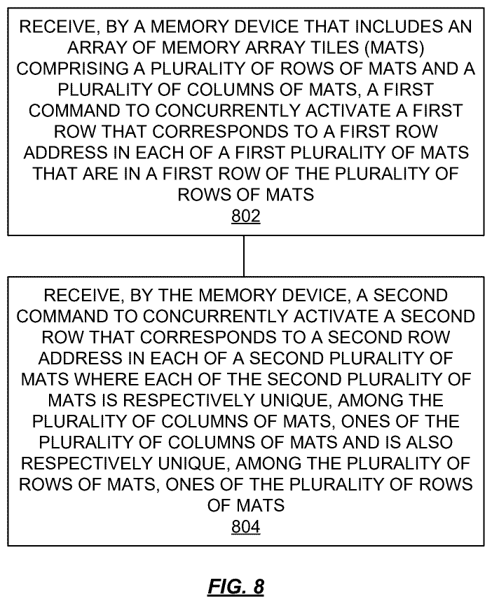

FIG. 8 is a flowchart illustrating a method of operating a memory controller to access a row page and a column page. One or more steps illustrated in FIG. 8 may be performed by, for example, memory system 100, memory system 200, memory array 500, and/or their components. By a memory device that includes an array of memory array tiles (MATs) comprising a plurality of rows of MATs and a plurality of columns of MATs, a first command to concurrently activate a first row that corresponds to a first row address in each of a first plurality of MATs that are in a first row of the plurality of rows of MATs is received (802). For example, memory device 210 may receive, from controller 220, a first command to concurrently activate a first row addressed by a first row address (e.g., MAT row address 1) in each of MATs 240ba-240bc.

By the memory device, a second command to concurrently activate a second row that corresponds to a second row address in each of a second plurality of MATs, where each of the second plurality of MATs is respectively unique, among the plurality of columns of MATs, ones of the plurality of columns of MATs and is also respectively unique, among the plurality of rows of MATs, ones of the plurality of roes of MATs (804). For example, memory device 210 may receive, from controller 220, a second command to concurrently activate a second row addressed by a second row address (e.g., MAT row address 0) in each of MAT 240ca, MAT 240ab, and MAT 240bc, where each of MAT 240ca, MAT 240ab, and MAT 240bc are in different physical MAT rows and different MAT columns from each other.

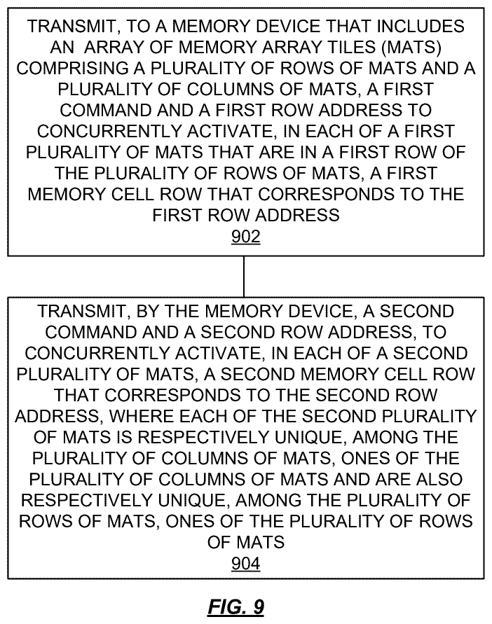

FIG. 9 is a flowchart illustrating a method of operating a memory device to access a row page and a column page. One or more steps illustrated in FIG. 9 may be performed by, for example, memory system 100, memory system 200, memory array 500, and/or their components. To a memory device that includes an array of memory array tiles (MATs) comprising a plurality of rows of MATs and a plurality of columns of MATs, a first command to concurrently activate a first row that corresponds to a first row address in each of a first plurality of MATs that are in a first row of the plurality of rows of MATs is transmitted (902). For example, controller 220 may transmit, to memory device 210, a first command to concurrently activate a first row addressed by a first row address (e.g., MAT row address 1) in each of MATs 240ba-240bc.

To the memory device, a second command to concurrently activate a second row that corresponds to a second row address in each of a second plurality of MATs is transmitted, where each of the second plurality of MATs is respectively unique, among the plurality of columns of MATs, ones of the plurality of columns of MATs and is also respectively unique, among the plurality of rows of MATs, ones of the plurality of roes of MATs (904). For example, controller 220 may transmit, to memory device 210, a second command to concurrently activate a second row addressed by a second row address (e.g., MAT row address 0) in each of MAT 240ca, MAT 240ab, and MAT 240bc, where each of MAT 240ca, MAT 240ab, and MAT 240bc are in different physical MAT rows and different MAT columns from each other.

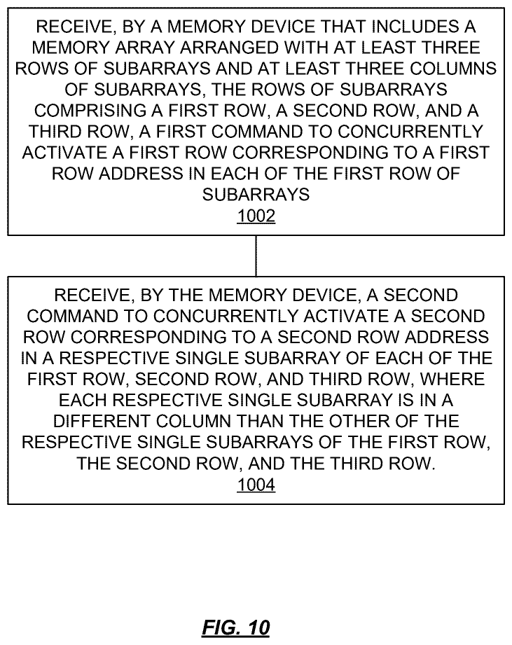

FIG. 10 is a flowchart illustrating a method of operating a memory device. One or more steps illustrated in FIG. 10 may be performed by, for example, memory system 100, memory system 200, memory array 500, and/or their components. By a memory device that includes a memory array arranged with at least three rows of subarray and at least three columns of subarray, the rows of subarrays comprising a first row, a second row, and a third row, a first command to concurrently activate a first row in each of the first row of subarrays is received (1002). For example, memory device 210 may receive, from controller 220, a first command to concurrently activate a first row addressed by a first row address (e.g., MAT row address 1) in each of MATs 240ba-240bc that are all in the same physical row of MATs in memory bank 240.

By the memory device, a second command to concurrently activate a second row correspond to a second row address in a respective single subarray of each of the first row, second row, and third row is received, where each respective single subarray is in a different column than the other of the respective single subarrays of the first row, the second row, and the third row (1004). For example, memory device 210 may receive, from controller 220, a second command to concurrently activate a second row addressed by a second row address (e.g., MAT row address 0) in each of MAT 240ca, MAT 240ab, and MAT 240bc, where each of MAT 240ca, MAT 240ab, and MAT 240bc are in different physical MAT array rows and different MAT array columns from each other.

The methods, systems and devices described above may be implemented in computer systems, or stored by computer systems. The methods described above may also be stored on a non-transitory computer readable medium. Devices, circuits, and systems described herein may be implemented using computer-aided design tools available in the art, and embodied by computer-readable files containing software descriptions of such circuits. This includes, but is not limited to one or more elements of memory system 100, memory system 200, memory array 500, and their components. These software descriptions may be: behavioral, register transfer, logic component, transistor, and layout geometry-level descriptions. Moreover, the software descriptions may be stored on storage media or communicated by carrier waves.

Data formats in which such descriptions may be implemented include, but are not limited to: formats supporting behavioral languages like C, formats supporting register transfer level (RTL) languages like Verilog and VHDL, formats supporting geometry description languages (such as GDSII, GDSIII, GDSIV, CIF, and MEBES), and other suitable formats and languages. Moreover, data transfers of such files on machine-readable media may be done electronically over the diverse media on the Internet or, for example, via email. Note that physical files may be implemented on machine-readable media such as: 4 mm magnetic tape, 8 mm magnetic tape, 3½ inch floppy media, CDs, DVDs, and so on.

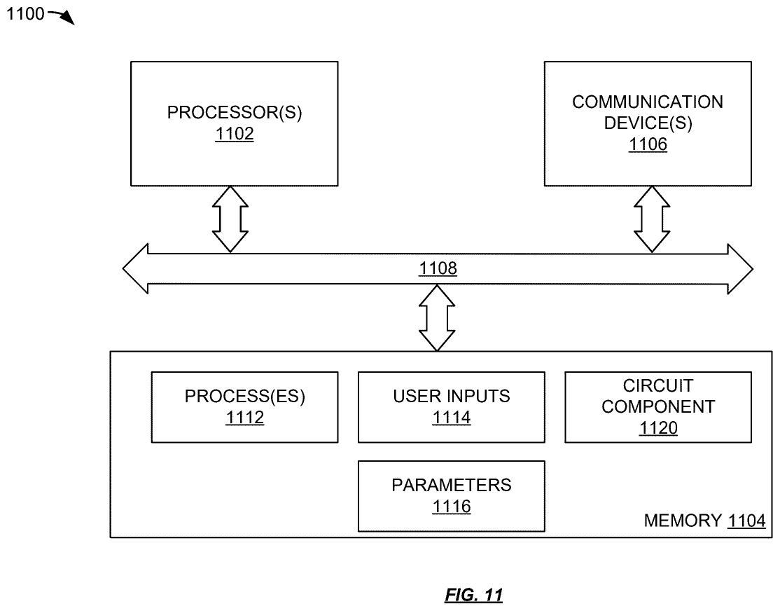

FIG. 11 is a block diagram illustrating one embodiment of a processing system 1100 for including, processing, or generating, a representation of a circuit component 1120. Processing system 1100 includes one or more processors 1102, a memory 1104, and one or more communications devices 1106. Processors 1102, memory 1104, and communications devices 1106 communicate using any suitable type, number, and/or configuration of wired and/or wireless connections 1108.

Processors 1102 execute instructions of one or more processes 1112 stored in a memory 1104 to process and/or generate circuit component 1120 responsive to user inputs 1114 and parameters 1116. Processes 1112 may be any suitable electronic design automation (EDA) tool or portion thereof used to design, simulate, analyze, and/or verify electronic circuitry and/or generate photomasks for electronic circuitry. Representation 1120 includes data that describes all or portions of memory system 100, memory system 200, memory array 500, and their components, as shown in the Figures.

Representation 1120 may include one or more of behavioral, register transfer, logic component, transistor, and layout geometry-level descriptions. Moreover, representation 1120 may be stored on storage media or communicated by carrier waves.

Data formats in which representation 1120 may be implemented include, but are not limited to: formats supporting behavioral languages like C, formats supporting register transfer level (RTL) languages like Verilog and VHDL, formats supporting geometry description languages (such as GDSII, GDSIII, GDSIV, CIF, and MEBES), and other suitable formats and languages. Moreover, data transfers of such files on machine-readable media may be done electronically over the diverse media on the Internet or, for example, via email

User inputs 1114 may comprise input parameters from a keyboard, mouse, voice recognition interface, microphone and speakers, graphical display, touch screen, or other type of user interface device. This user interface may be distributed among multiple interface devices. Parameters 1116 may include specifications and/or characteristics that are input to help define representation 1120. For example, parameters 1116 may include information that defines device types (e.g., NFET, PFET, etc.), topology (e.g., block diagrams, circuit descriptions, schematics, etc.), and/or device descriptions (e.g., device properties, device dimensions, power supply voltages, simulation temperatures, simulation models, etc.).

Memory 1104 includes any suitable type, number, and/or configuration of non-transitory computer-readable storage media that stores processes 1112, user inputs 1114, parameters 1116, and circuit component 1120.

Communications devices 1106 include any suitable type, number, and/or configuration of wired and/or wireless devices that transmit information from processing system 1100 to another processing or storage system (not shown) and/or receive information from another processing or storage system (not shown). For example, communications devices 1106 may transmit circuit component 1120 to another system. Communications devices 1106 may receive processes 1112, user inputs 1114, parameters 1116, and/or circuit component 1120 and cause processes 1112, user inputs 1114, parameters 1116, and/or circuit component 1120 to be stored in memory 1104.

Implementations discussed herein include, but are not limited to, the following examples:

Example 1: A memory device, comprising: a memory array comprising a plurality of rows of memory array tiles (MATs) and a plurality of columns of MATs; and a first interface to receive a first command and a second command, the first command to activate a first row, that corresponds to a first row address, in each of a first plurality of MATs, the first plurality of MATs to be in a first row of the plurality of rows of MATs of the memory array, the second command to activate a second row, that corresponds to a second row address, in each of a second plurality of MATs, each of the second plurality of MATs to respectively be in unique, among the plurality of columns of MATs, ones of the plurality of columns of MATs and to also respectively be in unique, among the plurality of rows of MATs, ones of the plurality of rows of MATs.

Example 2: The memory device of example 1, further comprising: a second interface to, based on a third command, communicate a first burst of data accessed via the first plurality of MATs, and to, based on a fourth command, communicate a second burst of data accessed via the second plurality of MATs.

Example 3: The memory device of example 2, wherein an order of data for the first burst of data corresponds to an order of column accesses to the first plurality of MATs, and an order of data for the second burst of data also corresponds to the order of column accesses to the second plurality of MATs.

Example 4: The memory device of example 2, further comprising: a buffer to communicate first data with the first plurality of MATs based on the first command and communicate second data with the second plurality of MATs based on the second command, the buffer to also communicate the first data with the second interface in a first burst order and to communicate the second data with the second interface in a second burst order.

Example 5: The memory device of example 4, wherein the first burst order corresponds to a matrix column order and the second burst order corresponds to a matrix row order.

Example 6: The memory device of example 5, wherein the matrix column order corresponds to ascending matrix column numbers.

Example 7: The memory device of example 5, wherein the matrix column order corresponds to ascending matrix row numbers.

Example 8: A memory device, comprising: a memory array arranged with at least three rows of subarrays and at least three columns of subarrays, the rows of subarrays comprising a first row, a second row, and a third row of subarrays; and a first interface to receive a first command and a second command, the first command to concurrently activate a first row corresponding to a first row address in each of the first row of subarrays, the second command to concurrently activate a second row, corresponding to a second row address, in a respective single subarray of each of the first row, the second row, and the third row, wherein each respective single subarray is to be in a different column than the other of the respective single subarray of the first row, the second row, and the third row.

Example 9: The memory device of example 8, further comprising: a second interface to, based on a third command, communicate a first burst of data accessed via the concurrent activation of the first row in each of the first row of subarrays, and to, based on a fourth command, communicate a second burst of data accessed via the concurrent activation of the second row in the respective single subarray of the first row, the second row, and the third row.

Example 10: The memory device of example 9, wherein the first row is concurrently activated in each of the first row of subarrays based on the memory device being in a first mode, and the second row is concurrently activated in the respective single subarray of each of the first row, the second row, and the third row based on the memory device being in a second mode.

Example 11: The memory device of example 10, wherein the first mode is based on the first command and the second mode is based on the second command.

Example 12: The memory device of example 9, wherein the first burst of data is accessed via the concurrent activation of the first row in each of the first row of subarrays based on the memory device being in a first mode, and the second burst of data is accessed via the concurrent activation of the second row in the respective single subarrays of the first row, the second row, and the third row based on the memory device being in a second mode.

Example 13: The memory device of example 12, wherein the first mode is based on the first command and the second mode is based on the second command.

Example 14: The memory device of example 9, further comprising: a buffer to communicate first data accessed via the concurrent activation of the first row in each of the first row of subarrays via the second interface in a first burst order, and communicate second data accessed via the concurrent activation of the second row in the respective single subarrays of the first row, the second row, and the third row via the second interface in a second burst order.

Example 15: A method of operating a memory device, comprising: in a first mode and based on a first command, concurrently activating a first respective row in each of a row of subarrays in an array of subarrays having rows of subarrays and columns of subarrays; and in a second mode and based on a second command, concurrently activating a second respective row in a respective single subarray of each of the rows of subarrays, wherein each respective single subarray is to be in a different column of subarrays than the other of the respective single subarrays.

Example 16: The method of example 15, further comprising: based on receiving the first command, entering the first mode; and based on receiving the second command, entering the second mode.

Example 17: The method of example 15, further comprising: based on receiving a first mode setting command, entering the first mode; and based on receiving a second mode setting command, entering the second mode.

Example 18: The method of example 15, further comprising: receiving a first plurality of data values associated with a row of a matrix to be communicated with the first respective row in each of the row of subarrays; and receiving a second plurality of data values associated with a column of the matrix to be communicated with the second respective row in the respective single subarray of each of the rows of subarrays.

Example 19: The method of example 18, further comprising: arranging, in a buffer, the first plurality of data values to be in a row order of the matrix.

Example 20: The method of example 18, further comprising: arranging, in a buffer, the second plurality of data values to be in a column order of the matrix.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. A memory device, comprising:
a memory array comprising a plurality of rows of memory array tiles (MATs) and a plurality of columns of MATs; and
a first interface to receive a first command and a second command, the first command to activate a first row, that corresponds to a first row address, in each of a first plurality of MATs, the first plurality of MATs to be in a first row of the plurality of rows of MATs of the memory array, the second command to activate a second row, that corresponds to a second row address, in each of a second plurality of MATs, each of the second plurality of MATs to respectively be in unique, among the plurality of columns of MATs, ones of the plurality of columns of MATs and to also respectively be in unique, among the plurality of rows of MATs, ones of the plurality of rows of MATs.

2. The memory device of claim 1, further comprising:
a second interface to, based on a third command, communicate a first burst of data accessed via the first plurality of MATs, and to, based on a fourth command, communicate a second burst of data accessed via the second plurality of MATs.

3. The memory device of claim 2, wherein an order of data for the first burst of data corresponds to an order of column accesses to the first plurality of MATs, and an order of data for the second burst of data also corresponds to the order of column accesses to the second plurality of MATs.

4. The memory device of claim 2, further comprising:
a buffer to communicate first data with the first plurality of MATs based on the first command and communicate second data with the second plurality of MATs based on the second command, the buffer to also communicate the first data with the second interface in a first burst order and to communicate the second data with the second interface in a second burst order.

5. The memory device of claim 4, wherein the first burst order corresponds to a matrix column order and the second burst order corresponds to a matrix row order.

6. The memory device of claim 5, wherein the matrix column order corresponds to ascending matrix column numbers.

7. The memory device of claim 5, wherein the matrix column order corresponds to ascending matrix row numbers.

8. A memory device, comprising:
a memory array arranged with at least three rows of subarrays and at least three columns of subarrays, the rows of subarrays comprising a first row, a second row, and a third row of subarrays; and
a first interface to receive a first command and a second command, the first command to concurrently activate a first row corresponding to a first row address in each of the first row of subarrays, the second command to concurrently activate a second row, corresponding to a second row address, in a respective single subarray of each of the first row, the second row, and the third row, wherein each respective single subarray is to be in a different column than the other of the respective single subarray of the first row, the second row, and the third row.

9. The memory device of claim 8, further comprising:
a second interface to, based on a third command, communicate a first burst of data accessed via the concurrent activation of the first row in each of the first row of subarrays, and to, based on a fourth command, communicate a second burst of data accessed via the concurrent activation of the second row in the respective single subarray of the first row, the second row, and the third row.

10. The memory device of claim 9, wherein the first row is concurrently activated in each of the first row of subarrays based on the memory device being in a first mode, and the second row is concurrently activated in the respective single subarray of each of the first row, the second row, and the third row based on the memory device being in a second mode.

11. The memory device of claim 10, wherein the first mode is based on the first command and the second mode is based on the second command.

12. The memory device of claim 9, wherein the first burst of data is accessed via the concurrent activation of the first row in each of the first row of subarrays based on the memory device being in a first mode, and the second burst of data is accessed via the concurrent activation of the second row in the respective single subarrays of the first row, the second row, and the third row based on the memory device being in a second mode.

13. The memory device of claim 12, wherein the first mode is based on the first command and the second mode is based on the second command.

14. The memory device of claim 9, further comprising:
a buffer to communicate first data accessed via the concurrent activation of the first row in each of the first row of subarrays via the second interface in a first burst order, and communicate second data accessed via the concurrent activation of the second row in the respective single subarrays of the first row, the second row, and the third row via the second interface in a second burst order.

15. A method of operating a memory device, comprising:
in a first mode and based on a first command, concurrently activating a first respective row in each of a row of subarrays in an array of subarrays having rows of subarrays and columns of subarrays; and
in a second mode and based on a second command, concurrently activating a second respective row in a respective single subarray of each of the rows of subarrays, wherein each respective single subarray is to be in a different column of subarrays than the other of the respective single subarrays.

16. The method of claim 15, further comprising:
based on receiving the first command, entering the first mode; and
based on receiving the second command, entering the second mode.

17. The method of claim 15, further comprising:
based on receiving a first mode setting command, entering the first mode; and
based on receiving a second mode setting command, entering the second mode.

18. The method of claim 15, further comprising:
receiving a first plurality of data values associated with a row of a matrix to be communicated with the first respective row in each of the row of subarrays; and
receiving a second plurality of data values associated with a column of the matrix to be communicated with the second respective row in the respective single subarray of each of the rows of subarrays.

19. The method of claim 18, further comprising:
arranging, in a buffer, the first plurality of data values to be in a row order of the matrix.

20. The method of claim 18, further comprising:
arranging, in a buffer, the second plurality of data values to be in a column order of the matrix.
